(19) United States
(12) Patent Application Publication
(10) Pub. No.: US 2014/0229133 A1
(43) Pub. Date: Aug. 14, 2014

(54) Method for Estimating Frequencies and Phases in Three Phase Power System

(71) Applicant: MITSUBISHI ELECTRIC RESEARCH LABORATORIES, INC., Cambridge, MA (US)

(72) Inventors: Zafer Sahinoglu, Cambridge, MA (US); Zhu Chen, Jersey City, NJ (US)

(73) Assignee: MITSUBISHI ELECTRIC RESEARCH LABORATORIES, INC., Cambridge, MA (US)

(21) Appl. No.: 13/764,836

(22) Filed: Feb. 12, 2013

(51) Int. Cl. G06F 17/14; G01R 23/02

(52) U.S. Cl. CPC G06F 17/14; G01R 23/02
USPC 702/75; 702/66

(57) ABSTRACT

Parameters of a three phase mixture of sinusoids with harmonic distortion are estimated by first acquiring samples of the signal for no more than a quarter cycle of the signal, a classifier is applied to the samples to obtain noise and signal parameters. Then, initial parameters are estimated to obtain final parameters.

### FIELD OF THE INVENTION

The invention relates generally to a three phase power system, and more particularly to estimating parameters such as frequencies and phases in the power system.

### BACKGROUND OF THE INVENTION

A major concern to ensure reliability in a power system is quality of the power, and to maintain signal parameters within predefined limits. The main parameters of power signals include voltage amplitude, phase angle, and fundamental frequency.

In the power system, frequency and phase estimation is used to maintain synchronism between the mains power grid and distributed generators and also for power system stabilization via generation and load matching. However, the frequency and phase of the power system can vary extremely fast during transient events, e.g., power surges, and voltage dips, and it becomes very difficult to track the frequency and phase with sufficient accuracy. Thus, fast and accurate frequency and phase estimation, in the presence of harmonic distortion and noise, remains a challenge.

Various methods are known for measuring the frequency and phase in the power system. A zero-crossing detection procedure is widely used, and easy to implement. However, that procedure requires appropriate filtering and long time sampling windows to obtain accurate measurement.

Filtering methods that use a discrete Fourier transform (DFT) and a recursive DFT procedure also need a long time window, which must be multiples of a fundamental cycle (period) to obtain accurate results.

A three-phase phase-locked loop (3PLL) circuit is frequently used to estimate and track the frequency of three-phase (3PH) power signals. Numerous techniques are known for constructing 3PLL circuits. However, in most cases, the 3PLL shows a transient response above one cycle of the fundamental cycle, or at best a response time of about half a cycle of the fundamental voltage component. Most procedures to estimate the frequency are based on the measurement of at least an entire phase of the system. Therefore, those procedures perform poorly when the tracked phase is subject to a very short voltage dip or a transient, a fraction of a cycle.

A Clarke's α,β transformation is widely used to convert 3PH quantities to a complex quantity in a 1-phase power system, which has a conventional harmonic signal model. The parameter estimator based on this 1-phase system is more accurate due to the utilization of the information from all the three-phase voltage.

The overall information from the 3PH voltage can be considered when designing frequency estimator. However, an adaptive FIR filter, which requires multiple of the fundamental cycle to eliminate the harmonics, is still required. MUltiple Signal Classifier (MUSIC) and Estimation of Signal Parameters via Rotational Invariance Technique (ESPRIT) can be used for high resolution estimation of the fundamental frequency and phase of the harmonic signal, see Schmidt, “Multiple emitter location and signal parameter estimation,” IEEE Trans. Antennas Propag., vol. 34, no. 3, pp. 276-280, March 1986, and Roy and Kailath, “Esprit-estimation of signal parameters via rotational invariance techniques,” IEEE Trans. Acoust., Speech, Signal Process., vol. 37, no. 7, pp. 984-995, July 1989. It is noted that the terms MUSIC for the classifier and ESPRIT for the estimation technique are used herein because this is how these techniques are known in the literature and to those of ordinary skill in the art, see e.g., U.S. Pat. No. 4,750,147, 1988.

FIG. 1 shows a prior art parameter estimation method 100 for a power system. Input 110 to a WLS estimator 120 is 3-phase mixture of sinusoidal signals 110 to obtain signal parameters 130.

FIG. 2 shows another prior art parameter estimation method 200. Input 210 to a classifier 220, i.e., MUSIC, is 1-phase mixture of sinusoidal signals 210 to obtain signal parameters 230.

### SUMMARY OF THE INVENTION

The embodiments of the invention provide a method for estimating fundamental frequencies and phases in a balanced and unbalanced three phase power system (3PH) with harmonic distortion. As an advantage the method operates on signal samples in only a quarter cycle, for example 20 samples with a sampling frequency of 4 kHz for a power grid operating at nominal frequency of 50 Hz.

Specifically, a model of the three-phase power system is converted to a noise-corrupted single phase harmonic signal model using a Clarke transformation.

A novel weighted least squares (WLS) parameter estimator is based on using the harmonic structure of the signal.

Due to the presence of harmonics in practical power systems, the method is made iterative to refine the initial estimation for the WLS estimator by exploting the estimates of the harmonic frequencies.

The method outperforms conventional estimators, i.e., the MUSIC. ESPRIT, or the WLS estimator alone with only quarter cycle samples.

### BRIEF DESCRIPTION OF THE DRAWINGS

FIG. 1 is a flow diagram of a prior art signal parameter estimation method using weighted least squares;

FIG. 2 is a flow diagram of a prior art signal parameter estimation method using MUSIC;

FIG. 3 is a flow diagram of a signal parameter estimation method according to embodiments of the invention;

FIG. 4 and FIG. 5 are flow diagrams of details of the signal parameter estimation method according to embodiments of the invention;

FIG. 6 is a schematic of a signal parameter estimation system according to embodiments of the invention; and

FIG. 7 is a graph of Cramér-Rao lower bounds as a function of signal to noise ratios.

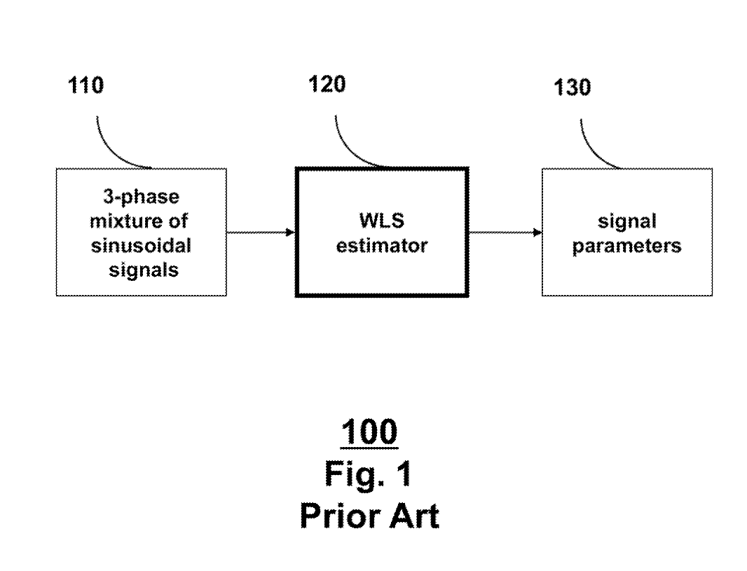

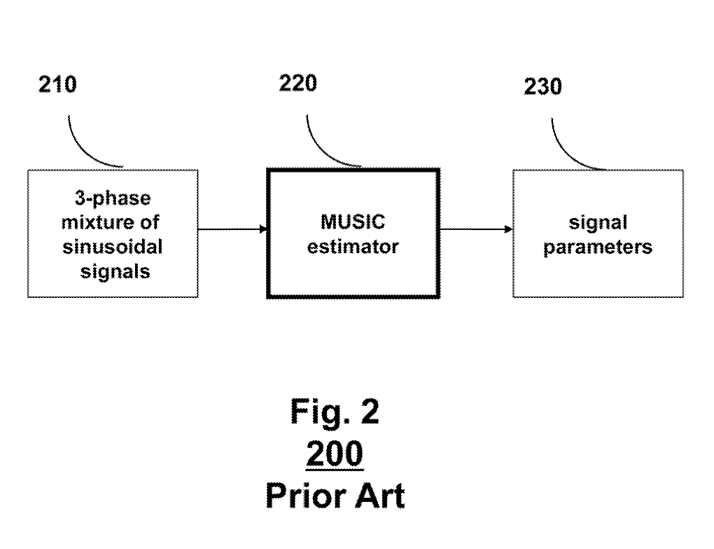

### DETAILED DESCRIPTION OF THE PREFERRED EMBODIMENTS

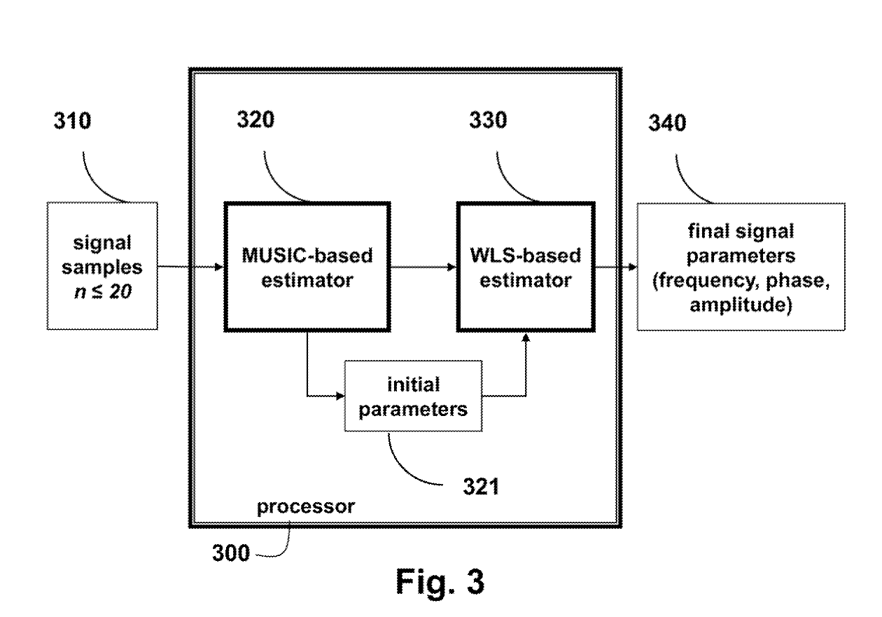

FIG. 3 shows a method for estimating parameters, such as frequencies and phases, of a three phase power system. Input to the method are samples of a 3-phase (3PH) mixture of sinusoidal signals 310. As an advantage, the samples are taken from less than a quarter of a fundamental cycle (period) of the signal. Taking more samples would certainly improve the accuracy of frequency estimate at a cost of increased computational complexity and latency.

A classifier, e.g., a low complexity fast-root MUltiple Signal Classifier (FRM), is applied 320 to the samples to obtain initial parameters 321. Then, a weighted least square (WLS) estimator is applied 330 to the initial parameters to refine the parameters and obtain the final parameters 340.

The method is iterative and can be performed in a processor 300 connected to memory and input/output interfaces as known in the art.

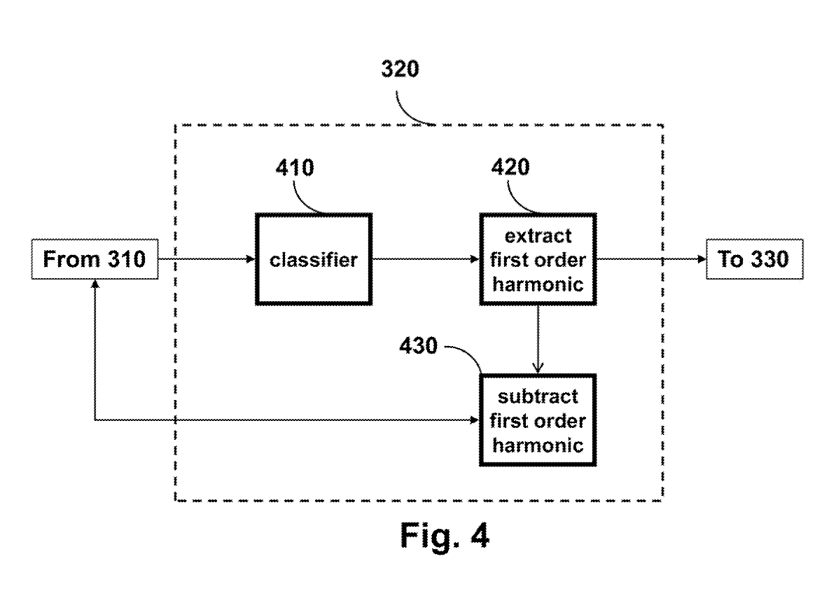

FIG. 4 shows the method steps in greater detail. The classifier 410 is applied to signal 310. A first order harmonic is extracted for step 330 that is the harmonic with the largest amplitude. The extracted signal component is subtracted 430 from the signal before for the next application of MUSIC.

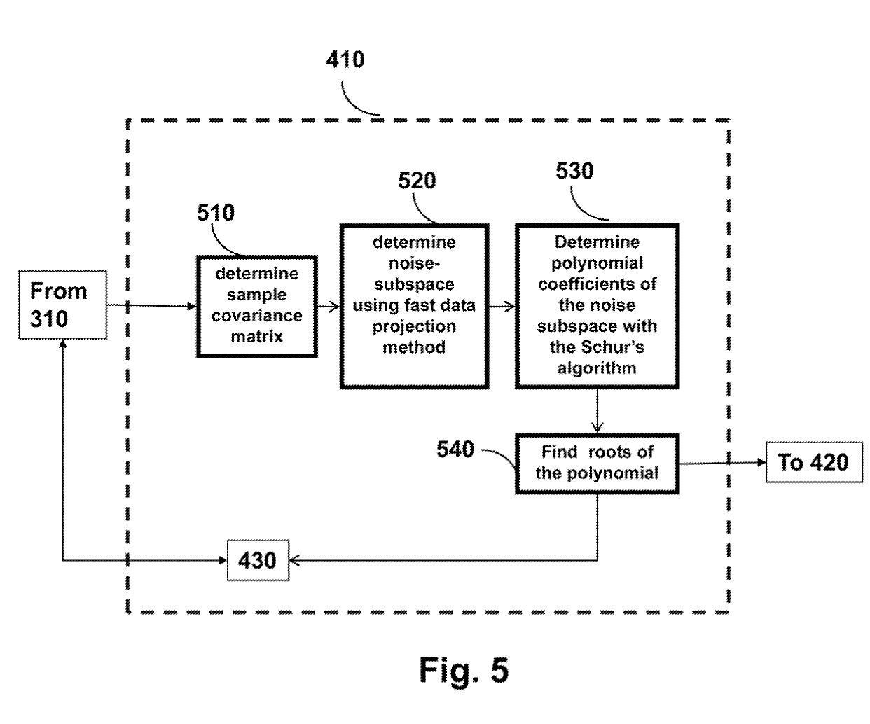

FIG. 5 shows the details of step 410. A covariance matrix is determined 510 from the samples. Then, a noise-subspace is determined 520 using fast data projection method. Polynomial coefficients of the noise subspace are determined 530 with the Schur algorithm, see Sayed et al., “A survey of spectral factorization methods,” Numerical Linear Algebra with Applications, vol, 8, pp. 467-496, July 2001. Roots 540 of the polynomial are passed to step 420.

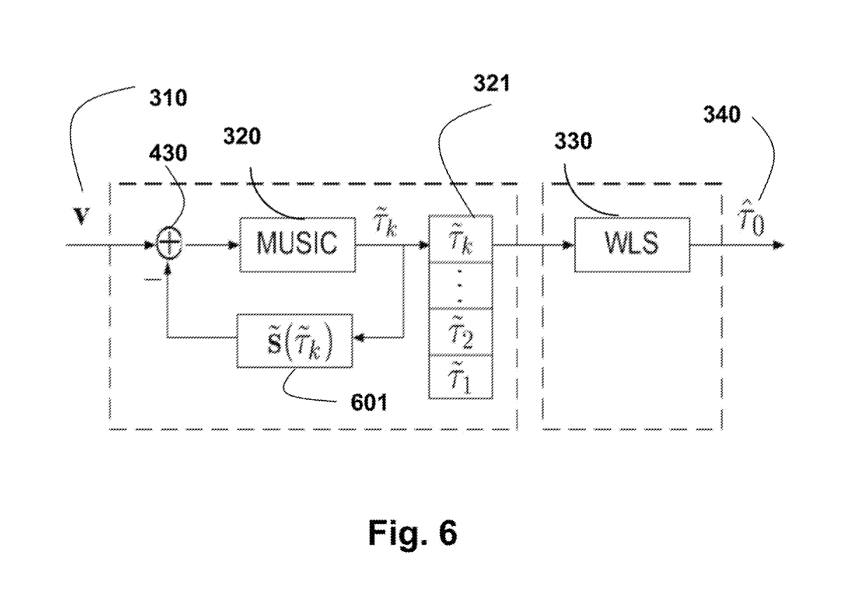

FIG. 6 shows an equivalent system that implements the parameter estimation. The variables shown in the figure are described in detail below, where v=[v(1) . . . v(N)]^{T} is the input sample vector and \hat{τ}₀={\hat{ω}₀, \hat{φ}, Â₁, . . . , Â_{K}} is the output parameter estimates. The estimated k^{th} harmonic component is s(\tilde{τ}ₖ)=[\tilde{s}(1) . . . \tilde{s}(N)]^{T} with \tilde{s}ₙ=Ãₖe^{j(n\tilde{ω}}^{ₖ}^{+\tilde{φ}}^{ₖ}⁾.

Signal Model in 3PH Power System

In a balanced three-phase (3PH) power system with K-1 harmonic distortion, the signal can be modeled as

$${v}_{a} ( n ) = {V}_{1} cos ( {ω}_{0} n + φ ) + {\sum }_{k = 2}^{K} {V}_{k} cos k ( {ω}_{0} n + φ ) + {ɛ}_{a} ( n ) \\ {v}_{b} ( n ) = {V}_{1} cos ( {ω}_{0} n + {φ}_{b} ) + {\sum }_{k = 2}^{K} {V}_{k} cos k ( {ω}_{0} n + {φ}_{b} ) + {ɛ}_{b} ( n ) \\ {v}_{c} ( n ) = {V}_{1} cos ( {ω}_{0} n + {φ}_{c} ) + {\sum }_{k = 2}^{K} {V}_{k} cos k ( {ω}_{0} n + {φ}_{c} ) + {ɛ}_{c} ( n ) , \qquad ( 1 )$$

where

$${φ}_{b} = φ - \frac{2}{3} π , \\ {φ}_{c} = φ + \frac{2}{3} π ,$$

n is a time instant of the sample, n=1, 2, . . . , N, ω₀ is the fundamental frequency with 0<|ω₀<π, and the phase φ∈[0,2π), Vₖ>0 is the amplitude of the k^{th} harmonic. A noise vector ε_{abc}(n)=[εₐ(n)ε_{b}(n)ε_{c}(n)]^{T} is a zero mean Gaussian random vector with covariance matrix σ²I.

For signal samples {vᵢ(n)}ₙ₌₁^{N} with i=a,b,c, the method estimates the unknown parameters, i.e., the fundamental frequency ω₀, and the phase φ of the signal. The current invention is also applicable to unbalanced three phase systems too. Processing of the voltages vₐ(n), v_{b}(n) and v_{c}(n) in an unbalanced system is not any different from the example given for balanced three-phase system.

Harmonic Signal Model in Single-Phase System

By applying the Clarke transformation to equation (1), we obtain the corresponding signal in an αβ stationary reference frame as

$$[ \begin{matrix}{v}_{α} ( n ) \\ {v}_{β} ( n )\end{matrix} ] = T [ \begin{matrix}{v}_{a} ( n ) \\ {v}_{b} ( n ) \\ {v}_{c} ( n )\end{matrix} ] , \qquad ( 2 )$$

where the transform matrix is

$$T = \frac{2}{3} [ \begin{matrix}1 & - \frac{1}{2} & - \frac{1}{2} \\ 0 & \frac{\sqrt{3}}{2} & - \frac{\sqrt{3}}{2}\end{matrix} ] , \qquad ( 3 )$$

Then, a complex voltage can be formed from the above transformation as

v(n)=v_{α}(n)+jv_{β}(n). (4)

If we define θ=ω₀n+φ as the phase angle of the 3PH system, then the voltage can be expressed as

v(n)=V₁e^{jθ}+V₂e^{-j2θ}+V₄e^{j4θ}+V₅e^{j5θ}+V₇e^{j7θ}+ . . . +ε(n), (5)

where ε(n)=ε_{α}(n)+jε_{β}(n), and

[ε_{α}(n)ε_{β}(n)]^{T}=T[68 ₐ(n)ε_{b}(n)ε_{c}(n)]^{T}

is a zero mean Gaussian random vector with covariance matrix

$$\frac{2}{3} {σ}^{2} I , .$$

The benefit of applying the Clarke transformation are as follows:
1) The multiples of three harmonic components are canceled out, and the signal only contains

$$K - ⌊ \frac{K}{3} ⌋$$

harmonies, which can reduce the amount of the measurement for parameter estimation;
2) The exponent sign of each harmonic changes alternatively in equation (5). In other words, the distance between two unknown parameters from the adjacent harmonics is increased. Hence, the estimation accuracy can be improved; and
3) The measurement can be synthesized from each single phase to provide a more reliable power system when subject to arbitrary phase dips, transients, or small interruptions.

Therefore, the equivalent harmonic signal model for the fundamental frequency and phase estimation in the power system is

$$v ( n ) = {\sum }_{k = 1}^{K} {A}_{k} {e}^{j {l}_{k} ( {ω}_{0} n + φ )} + ɛ ( n ) , \\ n = 1 , 2 , … , N , \qquad ( 6 )$$

where

$${l}_{k} = \frac{{( - 1 )}^{k - 1} ( 6 k - 3 ) + 1}{4} , \\ {A}_{k} = {V}_{\vert {l}_{k} \vert}$$

$$and$$

$$ɛ ( n ) \text{:} CW ( 0 , \frac{4}{3} {σ}^{2} ) .$$

There are a total of K harmonics involved in this model and the order of the k^{th} harmonic is lₖ.

Let v=[v(1) . . . v(N)]^{T} and ε∈ C^{N×1} be similarly formed from {ε(n)}ₙ₌₁^{N}. Then, equation (6) can be rewritten as

v=H(ω₀)γ+ε, (7)

where

$$γ = {[ {A}_{1} {e}^{j {l}_{1} φ} … {A}_{K} {e}^{j {l}_{K} φ} ]}^{T}$$

and H(ω₀)∈ C^{N×K} denotes the Vandermonde matrix with the k^{th} column given by

$${{h}_{k} [ {e}^{j {l}_{k} {ω}_{0}} {e}^{j {l}_{k} 2 {ω}_{0}} … {e}^{j {l}_{k} N {ω}_{0}} ]}^{T} .$$

We estimate ω₀, φ and Aₖ from the signal samples {v(n)}ₙ₌₁^{N}.

WLS Frequency and Phase Estimator

We extend the conventional WLS estimator for our signal Stoica et al., “Computationally efficient parameter estimation for harmonic sinusoidal signals,” Signal Process, vol. 80, pp. 1937-1944, 2000. The WLS ignores the harmonic structure, and uses a conventional sinusoidal parameter estimator, such as MUSIC and ESPRIT, to obtain the initial estimates 321: \tilde{ω}ₖ, \tilde{φ}ₖ and Ãₖ for ωₖ, φₖ and Aₖ respectively. Then, the WLS technique uses the structure of harmonics in the power system, i.e., ωₖ=lₖω₀ and φₖ=lₖφ, to refine 330 the initial estimation and produce the final parameters. Note that the amplitude estimates from the initial estimator 320 and the WLS are equivalent, because the amplitudes do not follow a harmonic structure, and applying the WLS does not lead to refining the estimate of Aₖ.

Specifically, let ζ=[l₁φ, l₁ω₀, . . . , l_{K}ω₀]^{T} ∈ [symbol] ^{2K×1}, and η=[φ,ω₀]^{T}. Then, there exists a rank-two matrix S=l [symbol] I₂, where l=[l₁, . . . , l_{K}]^{T}, so that

ζ=Sη, (8)

Let ζ=[\tilde{φ}₁, \tilde{ω}₁, . . . , \tilde{φ}_{K}, \tilde{ω}_{K}]^{T} be the corresponding initial estimate of ζ from MUSIC. The WLS estimator estimate \hat{η} of η is given b

$$η = arg {min}_{η} {‖ ζ - S η ‖}_{W}^{2} . \qquad ( 9 )$$

The weighting matrix W, obtained from the CRB matrix that does not consider the harmonic structure, is

$$W = [ \begin{matrix}2 N {\tilde{A}}_{k}^{2} & {N}^{2} {\tilde{A}}_{k}^{2} \\ {N}^{2} {\tilde{A}}_{k}^{2} & \frac{2}{3} {N}^{3} {\tilde{A}}_{k}^{2}\end{matrix} ] . \qquad ( 10 )$$

Then, we rewrite the cost function in equation (9) as

$$\begin{matrix}J ( ζ ) = {‖ \hat{ζ} - S η ‖}_{w}^{2} \\ = \frac{3}{4 {σ}^{2}} {\sum }_{k = 1}^{K} {[ \begin{matrix}{\tilde{φ}}_{k} - {l}_{k} φ \\ {\tilde{ω}}_{k} - {l}_{k} {ω}_{0}\end{matrix} ]}^{T} \times [ \begin{matrix}2 N {\tilde{A}}_{k}^{2} & {N}^{2} {\tilde{A}}_{k}^{2} \\ {N}^{2} {\tilde{A}}_{k}^{2} & \frac{2}{3} {N}^{3} {A}_{k}^{2}\end{matrix} ] [ \begin{matrix}{\tilde{φ}}_{k} - {l}_{k} φ \\ {\tilde{ω}}_{k} - {l}_{k} {ω}_{0}\end{matrix} ] \\ = \frac{3}{4 {σ}^{2}} {\sum }_{k = 1}^{K} {\tilde{A}}_{k}^{2} [ \begin{matrix}2 {N ( {\tilde{φ}}_{k} - {l}_{k} φ )}^{2} + 2 {N}^{2} ( {\tilde{φ}}_{k} - {l}_{k} φ ) ( {\tilde{ω}}_{k} - {l}_{k} {ω}_{0} ) + \\ \frac{2}{3} {{N}^{3} ( {\tilde{ω}}_{k} - {l}_{k} {ω}_{0} )}^{2}\end{matrix} ] .\end{matrix} \qquad ( 11 )$$

The solution of equation (9) can be expressed as follows. We differentiate equation (11) with respect to φ to obtain

$$\frac{d J}{d φ} = \frac{3}{4 {σ}^{2}} {\sum }_{k = 1}^{K} {\tilde{A}}_{k}^{2} [ 4 {Nl}_{k} ( {l}_{k} φ - {\tilde{φ}}_{k} ) + 2 {N}^{2} {l}_{k} ( {l}_{k} {ω}_{0} - {\tilde{ω}}_{K} ) ] . \qquad ( 12 )$$

Equating the expression to zero result in the estimate of φ as

$$\hat{φ} = \frac{{\sum }_{k = 1}^{K} {\tilde{A}}_{k}^{2} {l}_{k} ( 2 {\tilde{φ}}_{k} + N {\tilde{ω}}_{k} )}{{\sum }_{k = 1}^{K} 2 {\tilde{A}}_{k}^{2} {l}_{k}^{2}} - \frac{N}{2} {ω}_{0} , \qquad ( 13 )$$

where the right side of the equation depends on the unknown parameter ω₀. Substituting the above equation (13) into equation (11), and taking the differentiation w.r.t to ω₀, yields the WLS estimate of ω₀:

$${\hat{ω}}_{0} = \frac{{\sum }_{k = 1}^{K} {l}_{k} {\tilde{A}}_{k}^{2} {\tilde{ω}}_{k}}{{\sum }_{k = 1}^{K} {l}_{k}^{2} {\tilde{A}}_{k}^{2}} . \qquad ( 14 )$$

Using the above \hat{ω}₀ to replace ω₀ in equation (13), we can obtain the WLS estimate of φ as

$$\hat{φ} = \frac{{\sum }_{k = 1}^{K} {l}_{k} {\tilde{A}}_{k}^{2} {\tilde{φ}}_{k}}{{\sum }_{k = 1}^{K} {l}_{k}^{2} {\tilde{A}}_{k}^{2}} . \qquad ( 15 )$$

Hence, equations (14) and (15) provide closed-form expressions for the WLS estimates of the frequency and phase parameters. Because \hat{ω} and \hat{φ} are weighted linear regression over {\tilde{ω}ₖ}ₖ₌₁^{K} and {\tilde{φ}}ₖ₌₁^{K}, respectively, by using the harmonic structure, the WLS estimator can extract the useful information from the harmonic distortion. The performance is very close to the CRB with a large number of samples, see the Appendix for the derivation of the CRB.

Improved WLS Estimator for Power System with Limited Samples

We first describe our method for the WLS estimator when applied to a very small number of samples in a power signal, e.g., only quarter cycle samples are available for the estimation. Then, we describe our improved WLS (IWLS) estimator, based on an iterative MUSIC.

Disadvantage of WLS in 3PH Power System

The conventional WLS estimator performs adequately when the non-primary harmonics have comparable amplitudes with first order harmonics. Unfortunately, with very low harmonic distortion in the 3PH power system, the conventional WLS estimator loses its advantage for a small number of samples. The reason is that, with limited samples, the estimation accuracy for the unknown parameters of non-primary harmonics with weak power is not guaranteed. Thus, the unreliable information used in conventional WLS estimator decreases the estimation performance.

Therefore, we provide a method that can provide reliable initial estimation for the WLS estimator even with a very small number of samples.

IWLS Parameter Estimation

We use MUSIC as the estimator for the initial parameters 321. MUSIC tracks 420 the unknown parameters of the first order harmonics. This is a desired property for our iterative method. Moreover, the MUSIC is generally sensitive to the choice of M relative to the number of samples N, where M is the length of the subvectors used in MUSIC. This is an inherent trade-off between having many subvectors in the averaging while retaining sufficient dimensions of the harmonics. We know that when M=4N/5, MUSIC always provides good estimation on the unknown parameters of the first order harmonic, therefore, M=4N/5 is preferred, especially when the number of sample is small.

Our estimation method uses a two-step procedure: initial estimation using MUSIC, and a refined estimation using WLS. Because the initial estimation for the unknown parameters of the harmonics with small amplitudes is inaccurate, in the small sample case, we provide an iterative WLS (IWLS) estimator to refine the initial estimation.

Specifically, with a sample vector v, we can use MUSIC to estimate the initial parameters {\tilde{ω}ₖ, \tilde{φ}ₖ, Ãₖ}ₖ₌₁^{K} of all the K harmonics. However, we only retain the most accurate and reliable estimation \tilde{τ}₁={\tilde{ω}₁, \tilde{φ}₁, Ã₁}, which corresponds to the harmonic with largest amplitude, i.e., the first order harmonic. With \tilde{τ}₁, we can approximately construct the first order harmonic s(\tilde{τ}₁) 601. Therefore, we subtract this estimated harmonic component from the sample vector, and then apply MUSIC again on this vector which now only has K-1 harmonics to obtain the estimation \tilde{τ}₂ of the second order harmonic by saving the estimation corresponding to the K-1 remaining first order harmonics. We continue the iteration with K steps. We can save all the K initial parameters {\tilde{τ}₁, . . . , \tilde{τ}_{K}} for the refined estimation phase.

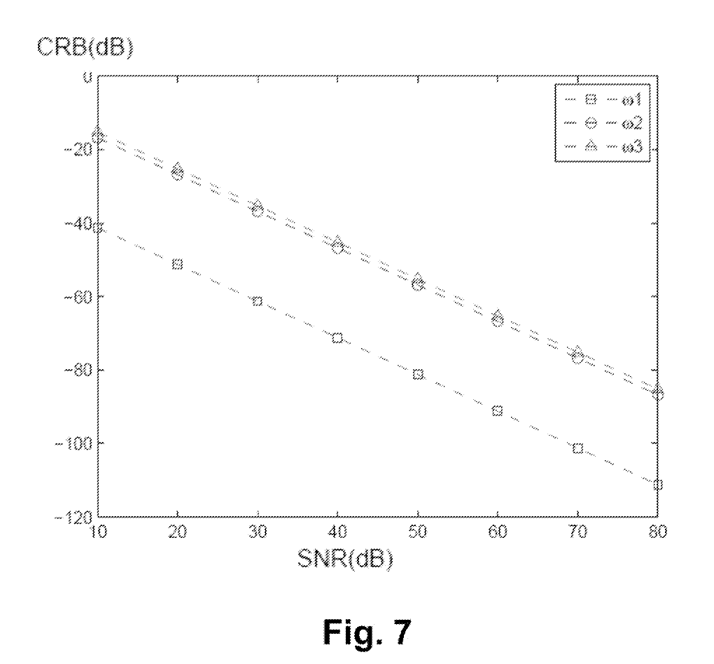

FIG. 7 shows the CRBs as a function of the frequencies with three harmonies involved in the signal with independent frequency ω₁, ω₂, ω₃. The corresponding amplitudes are A₁=1, A₂=0.06, A₃=0.05, respectively. The number of sample is 20, and the CRB is determined in terms of

$$\frac{1}{{σ}^{2}} W ,$$

where σ² is the power of noise, and the weighting matrix W is given in equation (10) A harmonic with larger amplitude has a lower CRB for its frequency estimate. Therefore, the accuracy (acc) or the reliability of the three frequency estimates satisfies

acc(\hat{ω}₁)>acc(\hat{ω}₂)>acc(\hat{ω}₃),

where acc(\hat{ω}) denotes the accuracy of \hat{ω}.

Recall that the frequency estimator in equation (14) and phase estimator in equation (15) are weighted linear combination over {\tilde{ω}ₖ}ₖ₌₁^{K} and {\tilde{φ}}ₖ₌₁^{K}, respectively. However, with only quarter cycle samples, or a low SNR, not all of the K parameters can be estimated accurately. Therefore, we only use the estimates of the first k, k<K, harmonics to estimate ω₀ and φ.

In other words, we only preform k iterations, rather than going through all K iterations. Note, we only implement the iteration in the initial estimation when the number of samples is small. Therefore, the computational complexity introduced by the iterations is acceptable.

Computational Complexity Analysis and Fast Implementation

Our method involves two major steps: initial parameter estimation with the k iterative MUSIC, and refined estimation with the WLS estimator. The WLS estimator is basically a linear operation on the initial estimation with computational complexity of O(1) therefore the computational cost of IWLS estimator is mainly determined by that of MUSIC.

The length of the vector used for determining the sample covariance matrix is M=4N/5 The computational burden is mainly due to the eigenvalue decomposition of the sample covariance matrix with 23M³ flops, and determining the roots of the 2M−2 degree polynomial. Finding the 2M−2 roots of the polynomial is equivalent to finding the 2M−2 eigenvalues of its corresponding companion matrix which requires 16/3(2M−2) flops. Thus, the dominative complexity of MUSIC is

$$cost ( RM ) = \frac{191}{3} {M}^{3} + ( 6 N - 4 K - 124 ) {M}^{2} + ( 2 N + 130 ) M .$$

In an adaptive context, tracking the model parameters by recursively applying the proposed procedure is time consuming. Hence, there is a clear need for a fast implementations of the IWLS estimator. A fast root-MUSIC (FRM) estimation provides an efficient algorithm with smaller computational burden by significantly reducing the complexity of finding the roots of a polynomial see Zhuang et al., “Fast root-music for arbitrary arrays,” Elec. Letters, vol. 46, no. 2, pp. 174-176, January 2010.

Because the polynomial f(z) with 2M−2 degree can be factorize as f(z)=cf₁(z)f₁*(1/z*), where c is a positive constant, and the roots of f(z) appear in conjugate reciprocal pairs. Finding the half roots, i.e., roots of f₁(z) with M−1 degree is sufficient.

Fast-Root Music Based Estimator

The fast-root MUSIC can be summarized as follows.
1.) Determining the sample covariance matrix R:

$$R = \frac{1}{N - M + 1} {\sum }_{j = 1}^{N - M + 1} {x}_{j} {x}_{j}^{H}$$

where xⱼ ∈ C^{M×1} is a truncated version of v.
2.) Performing eigenvalue decomposition of R yields the noise subspace E and construct A=EE^{H} with A(m,n) as its (m,n)^{th} entry.
3.) Determining the partial coefficients of the 2M−2 polynomial f(z) by

$${b}_{i} = {\sum }_{m - n = i} A ( m , n )$$

with i=−(M−1), −(M−2), . . . , 0.
4.) Finding the M coefficient f₁(z) using the Schur algorithm:
   (a) Construct the initial matrix B₀ ∈ [symbol] ^{M×2} in terms of bᵢ:
   (b) For i=1,2, . . . , I, iterate the following steps:
      i. Bᵢ=Bᵢ₋₁Uᵢ, where Uᵢ∈ C^{2×2} is defined as

$${U}_{i} = \frac{1}{\sqrt{1 - {\vert γ \vert}^{2}}} [ \begin{matrix}1 & - γ \\ - {γ}^{*} & 1\end{matrix} ] .$$

with γ=Bᵢ₋₁(1,2)/Bᵢ₋₁(1,1).
   ii. Shift up the second column of Bᵢ by one element while keeping the first column unaltered.
(c) The coefficients of f₁(z) are given by b*_{1,i}, where b_{1,i} is the first column of Bᵢ.
5.) Finding the M−1 roots of f₁(z) which is equivalent to finding the M−1 eigenvalues of its corresponding companion matrix M.

In the above procedure, step 2 needs 23M³ flops to determine the noise subspace vectors by the eigenvalue decomposition. This time-consuming operation can be avoided by recursively updated E.

Fast Projection Method

Therefore, the following fast projection method is provided.

Previous instant: E(n-1), new data: v(n), n>N

Apply:

$$1. Construc t the new subvector$$

$${x}_{n} = {[ v ( n - M + 1 ) , … , v ( n - 1 ) , v ( n ) ]}^{T}$$

$$2. y ( n ) = {E}^{H} ( n - 1 ) x ( n )$$

$$3. z ( n ) = E ( n - 1 ) y ( n )$$

$$4. r ( n ) = \frac{z ( n )}{‖ y ( n ) ‖} + β x ( n ) ‖ y ( n ) ‖$$

$$5. q ( n ) = \frac{r ( n )}{‖ r ( n ) ‖} - \frac{z ( n )}{‖ y ( n ) ‖}$$

$$6. E ( n ) = E ( n - 1 ) + q ( n ) \frac{{y}^{H} ( n )}{‖ y ( n ) ‖}$$

The embodiments of the invention solves a frequency and phase estimation problem in three phase (3PH) power system with no more than quarter cycle samples. The model of the 3PH power system with harmonic distortion is converted to a noise-corrupted single-phase harmonic signal model.

A novel WLS frequency estimator and phase estimator is provided. Due to the low voltage characteristic of the non-primary harmonic and the small number of samples, an improved WLS estimator is provided, which uses an iterative procedure to refine the initial parameter of the WLS estimator.

Although the examples given herein are for a balanced 3 PH power system, the invention can also be used for other 3PH power systems such as the ones with voltage and phase unbalanced, without changing the algorithms described according to the current invention.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

### APPENDIX

### Cramér-Rao Lower Bound

We derive the CRB for the parameter estimation problem posed for the complex data model in equation (6). By defining η=[φ, ω₀, α^{T}]^{T} ∈ [symbol] ^{(K+2)×1}, and letting a^{T}=[A₁, . . . , A_{K}], we rewrite equation (7) as

v=B(ω₀, φ)a+ε=x(η)+ε, (16)

where B(ω₀, φ)∈ C^{N×K} with its kth column is defined by bₖ=e^{jl}^{ₖ}^{φ}hₖ.

By using the Slepian-Bangs formula, the CRB matrix for the problem is given by

$$C R {B}^{- 1} ( η ) = \frac{3}{2 {σ}^{2}} ℜ [ \frac{\partial {x}^{H} ( η )}{\partial η} \frac{\partial x ( η )}{\partial {η}^{T}} ] , \qquad ( 17 )$$

Then, we evaluate the partial derivatives as follows:

$$\begin{matrix}\frac{\partial z ( η )}{\partial {η}^{T}} = [ \frac{\partial x ( η )}{\partial φ} , \frac{\partial x ( η )}{\partial {ω}_{0}} , \frac{\partial x ( η )}{\partial {a}^{T}} ] , \\ where & ( 18 ) \\ \frac{\partial x ( η )}{\partial φ} = Ca , & ( 19 ) \\ \frac{\partial x ( η )}{\partial {ω}_{0}} = Da , \\ and & ( 20 ) \\ \frac{\partial x ( η )}{\partial {a}^{T}} = B , & ( 21 )\end{matrix}$$

with the kth columns of C ∈ C^{N×K} and D ∈ C^{N×K} given by cₖ=jlₖbₖ and

$${d}_{k} = j {l}_{k} {{e}^{j {l}_{k} φ} [ {e}^{j {l}_{k} {ω}_{0}} , 2 {e}^{j {l}_{k} 2 {ω}_{0}} , … , N {e}^{j {l}_{k} N {ω}_{0}} ]}^{T} ,$$

respectively,

Then, it follows that

$$C R B ( \overline{η} ) = \frac{2 {σ}^{2}}{3} {\{ ℜ [ \begin{matrix}{a}^{H} {C}^{H} Ca & {a}^{H} {C}^{H} Da & {a}^{H} {C}^{H} B \\ {a}^{H} {D}^{H} Ca & {a}^{H} {D}^{H} Da & {a}^{H} {D}^{H} B \\ {B}^{H} Ca & {B}^{H} Da & {B}^{H} B\end{matrix} ] \}}^{- 1} . \qquad ( 22 )$$

We claim:

1. A method for estimating parameters of a signal, wherein the signal is a three phase mixture of sinusoids with harmonic distortion, comprising the steps of:
acquiring samples of the signal for no more than a quarter cycle of the signal;
applying a classifier to the samples to obtain noise and signal parameters; and
applying an estimator to the initial parameters to obtain final parameters.

2. The method of claim 1, wherein the classifier is a multiple signal classifier (MUSIC), which iteratively performs the steps of:
extracting a strongest harmonic from the signal for the estimator; and
subtracting the first order harmonics from the signal before a next iteration.

3. The method of claim 2, wherein the classifier comprises the steps of:
constructing a covariance matrix from the sample;
determining a noise subspace from an eigenvalue decomposition of the covariance matrix;
determining polynomial coefficients of the noise subspace; and
passing roots of the polynomial coefficients to the extracting step.

4. The method of claim 1, wherein the parameters include a frequency, a phase, and amplitude of the signal.

5. The method of claim 1, further comprising:
applying a Clarke transform to the signal.

6. The method of claim 1, wherein a number of samples is less than the number of samples obtained in a time period longer than one quarter cycle of a fundamental frequency of the signal.

7. The method of claim 1, wherein the estimator is a weighted least square (WLS) estimator.
